(19) United States
(12) Patent Application Publication
(10) Pub. No.: US 2026/0324061 A1
(43) Pub. Date: Oct. 15, 2026

(54) SEMICONDUCTOR DEVICE

(71) Applicant: SAMSUNG ELECTRONICS CO., LTD., Suwon-si (KR)

(72) Inventors: Songjae LEE, Suwon-si (KR); Soohun HONG, Suwon-si (KR); Moon Seung YANG, Suwon-si (KR)

(73) Assignee: SAMSUNG ELECTRONICS CO., LTD., Suwon-si (KR)

(21) Appl. No.: 19/363,770

(22) Filed: Oct. 21, 2025

(30) Foreign Application Priority Data
Apr. 15, 2025 (KR) 10-2025-0048704

(51) Int. Cl. H10D 84/83; H10D 30/00; H10D 30/01; H10D 62/13; H10D 62/40; H10D 64/23; H10D 84/01

(52) U.S. Cl. CPC H10D 84/832; H10D 30/503; H10D 30/506; H10D 62/151; H10D 62/405; H10D 64/256; H10D 30/0191; H10D 84/013

(57) ABSTRACT

A semiconductor device comprises a fin pattern, a source/drain pattern disposed on the fin pattern, a channel structure connected to the source/drain pattern, and a gate electrode overlapping the channel structure. The source/drain pattern comprises an overlap portion overlapping with the fin pattern, and a first side portion and a second side portion spaced apart from each other with the overlap portion interposed therebetween. The first side portion comprises a first lower sidewall. The second side portion comprises a second lower sidewall opposite to the first lower sidewall. A level of an uppermost portion of the first lower sidewall is lower than that of a lowermost portion of the second lower sidewall. A volume of the first side portion is larger than that of the second side portion.

### CROSS-REFERENCE TO RELATED APPLICATIONS

This U.S. non-provisional patent application claims priority under 35 U.S.C. § 119 to Korean Patent Application No. 10-2025-0048704, filed on Apr. 15, 2025, in the Korean Intellectual Property Office, the entire contents of which are hereby incorporated by reference.

### BACKGROUND

A semiconductor device includes an integrated circuit composed of MOS (Metal Oxide Semiconductor) field effect transistors (MOSFET). As the size and design rule of the semiconductor device gradually shrink, a scale down of the MOS field effect transistors is also gradually accelerating. As the size of the MOS field effect transistors shrinks, operating characteristics of the semiconductor device may deteriorate. Accordingly, various methods have been studied for forming the semiconductor device with better performance while overcoming limitations due to high integration of the semiconductor device.

### SUMMARY

According to an aspect of the disclosure, a semiconductor device may include a fin pattern; a source/drain pattern disposed on the fin pattern; a channel structure connected to the source/drain pattern; and a gate electrode overlapping the channel structure. The source/drain pattern may comprise an overlap portion overlapping with the fin pattern; and a first side portion and a second side portion spaced apart from each other with the overlap portion interposed therebetween. The first side portion may comprise a first lower sidewall. The second side portion may comprise a second lower sidewall opposite to the first lower sidewall. A level of an uppermost portion of the first lower sidewall may be lower than that of a lowermost portion of the second lower sidewall. A volume of the first side portion may be larger than that of the second side portion.

According to an aspect of the disclosure, a semiconductor device may include a substrate; a fin pattern disposed on the substrate; a source/drain pattern disposed on the fin pattern; a channel structure connected to the source/drain pattern; and a gate electrode overlapping the channel structure. An upper surface of the substrate may be inclined at a first angle with respect to a {100} crystal plane of the substrate.

According to an aspect of the disclosure, a semiconductor device may include a fin pattern; a source/drain pattern disposed on the fin pattern; a channel structure connected to the source/drain pattern; a gate insulating layer disposed on the channel structure; a gate electrode disposed on the gate insulating layer; and an active contact disposed on the source/drain pattern. The source/drain pattern may comprise an overlap portion overlapping with the fin pattern; and a first side portion and a second side portion spaced apart from each other with the overlap portion interposed therebetween. The first side portion may comprise a first lower sidewall. The second side portion may comprise a second lower sidewall opposite to the first lower sidewall. The fin pattern may comprise a first sidewall adjacent the first lower sidewall and a second sidewall adjacent the second lower sidewall. An angle between the first lower sidewall and the first sidewall of the fin pattern may be less than that between the second lower sidewall and the second sidewall of the fin pattern. A volume of the first side portion may be larger than that of the second side portion.

According to an aspect of the disclosure, a method of manufacturing a semiconductor device may include etching a preliminary substrate to form a substrate and a fin pattern; forming a source/drain pattern on the fin pattern; and forming a gate electrode overlapping the fin pattern. An upper surface of the substrate may be inclined with respect to a {100} crystal plane of the substrate.

According to an aspect of the disclosure, a sidewall of the fin pattern may be inclined with respect to a {111} crystal plane of the substrate.

### BRIEF DESCRIPTION OF THE DRAWINGS

FIG. 1A is a top view of a semiconductor device according to some embodiments.

FIG. 1B is a cross-sectional view taken along line A-A′ in FIG. 1A.

FIG. 1C is a cross-sectional view taken along line B-B′ of FIG. 1A.

FIG. 1D is an enlarged view of a Q1 region of FIG. 1B.

FIGS. 2, 3, 4, 5A, and 5B are diagrams for describing a method of manufacturing a semiconductor device according to some embodiments.

FIG. 6 is an enlarged cross-sectional view of a semiconductor device according to some embodiments.

FIG. 7 is an enlarged cross-sectional view of a semiconductor device according to some embodiments.

FIG. 8 is an enlarged cross-sectional view of a semiconductor device according to some embodiments.

FIGS. 9A and 9B are cross-sectional views of a semiconductor device according to some embodiments.

### DETAILED DESCRIPTION

Example embodiments of the inventive concepts will now be described more fully with reference to the accompanying drawings, in which example embodiments are shown.

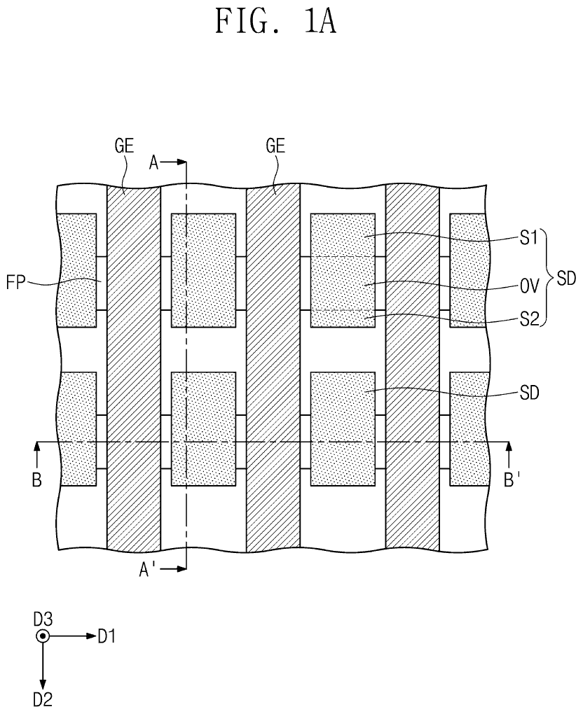

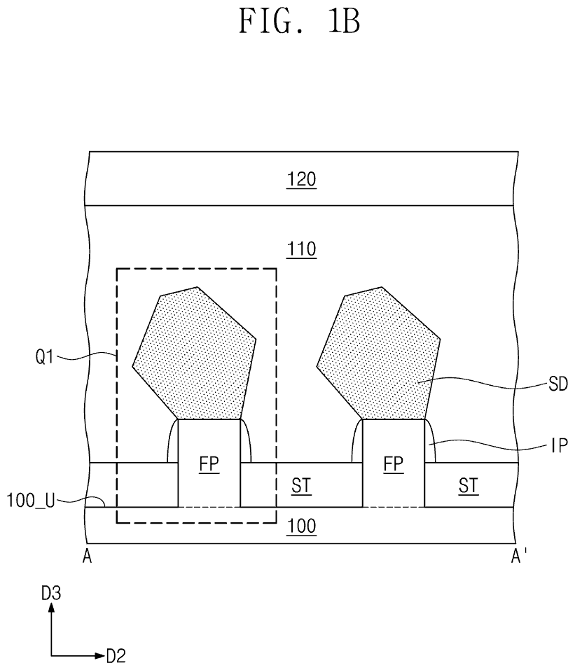

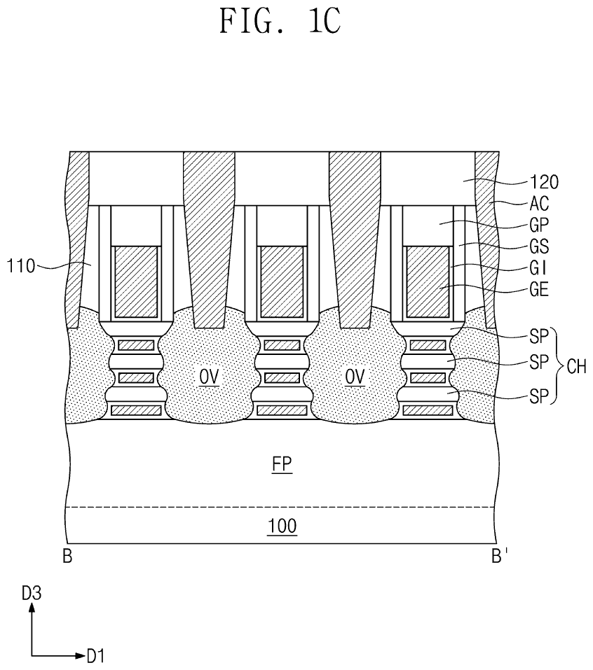

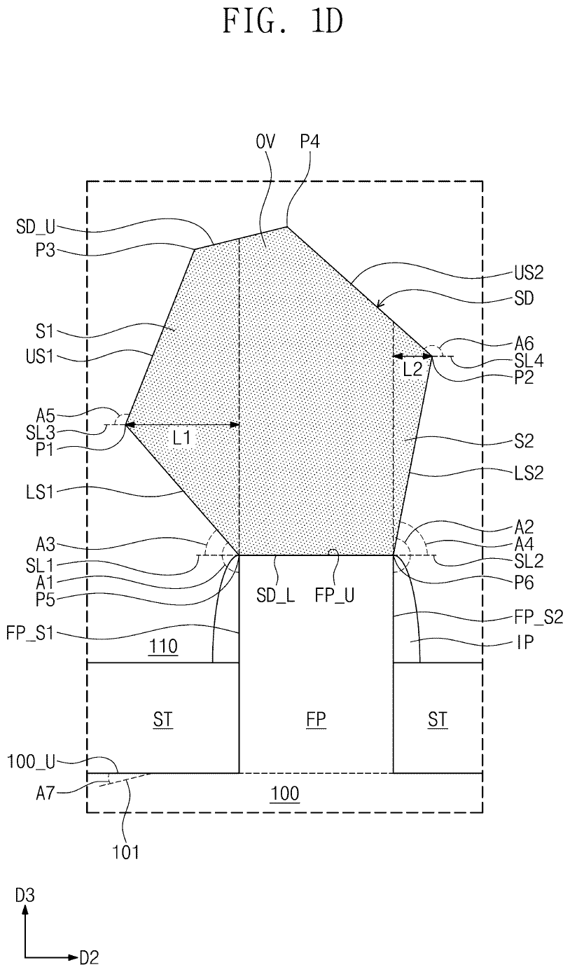

FIG. 1A is a top view of a semiconductor device according to some embodiments. FIG. 1B is a cross-sectional view taken along line A-A′ in FIG. 1A. FIG. 1C is a cross-sectional view taken along line B-B′ of FIG. 1A. FIG. 1D is an enlarged view of a Q1 region of FIG. 1B.

Referring to FIGS. 1A, 1B, and 1C, a semiconductor device may include a substrate 100.

An upper surface 100_U of the substrate 100 may be parallel to a plane defined by a first direction D1 and a second direction D2. The first direction D1 and the second direction D2 may intersect with each other. As an example, the first direction D1 and the second direction D2 may be horizontal directions orthogonal to each other.

The substrate 100 may be a semiconductor substrate, an insulator substrate, or a semiconductor-on-insulator (SOI) substrate. The semiconductor substrate may comprise, for example, silicon, germanium, silicon-germanium, GaP or GaAs.

A fin pattern FP may be provided on the substrate 100. The fin pattern FP may protrude from the upper surface 100_U of the substrate 100 in a third direction D3. The third direction D3 may intersect the first direction D1 and the second direction D2. As an example, the third direction D3 may be a vertical direction orthogonal to the first direction D1 and the second direction D2. The fin pattern FP may include a semiconductor material.

The fin pattern FP and the substrate 100 may include the same material as each other. The fin pattern FP and the substrate 100 may be connected to each other without boundaries to form an integral structure.

In some embodiments, the substrate 100 may be omitted, and the fin pattern FP may be provided on a lower insulating layer. In this case, the fin pattern FP may include a semiconductor material or an insulating material.

A device isolation layer ST may be provided on the substrate 100. The device isolation layer ST may be provided on the upper surface 100_U of the substrate 100. The device isolation layer ST may surround the fin pattern FP. The device isolation layer ST may include an insulating material. For example, the device isolation layer ST may include an oxide. In some embodiments, the device isolation layer ST may be a multiple layer including a plurality of insulating layers.

An insulation pattern IP may be provided on the device isolation layer ST. The insulating pattern IP may be provided on a sidewall of the fin pattern FP. The insulating pattern IP may be in contact with the sidewall of the fin pattern FP. The insulating pattern IP may include an insulating material. In some embodiments, the insulating pattern IP may be a multiple layer including a plurality of insulating layers.

A source/drain pattern SD may be provided on the fin pattern FP. The source/drain pattern SD may be an epitaxial pattern formed by a selective epitaxial growth (SEG) process. The source/drain pattern SD may include a semiconductor material. As an example, the source/drain pattern SD may include at least one of silicon (Si), silicon-germanium (SiGe), or germanium (Ge). The source/drain pattern SD may be doped with dopants.

A channel structure CH overlapping the fin pattern FP in the third direction D3 may be provided. The channel structure CH may include the semiconductor patterns SP overlapping in the third direction D3. In some embodiments, the semiconductor pattern SP may include silicon (Si). For example, the semiconductor pattern SP may include crystalline silicon. In some embodiments, the semiconductor pattern SP may include silicon-germanium (SiGe).

A gate electrode GE overlapping the channel structure CH in the third direction D3 may be provided. The gate electrode GE may include a portion interposed between the semiconductor patterns SP. The gate electrode GE may include a conductive material. The semiconductor pattern SP of the channel structure CH and the gate electrode GE may constitute a three-dimensional field effect transistor (e.g., MBCFET or GAAFET).

A gate insulating layer GI may be provided. The gate insulating layer GI may be in contact with the gate electrode GE. The gate insulating layer GI may separate the gate electrode GE from the source/drain pattern SD and the semiconductor pattern SP. The gate insulating layer GI may include an insulating material. For example, the gate insulating layer GI may include an oxide. In some embodiments, the gate insulating layer GI may be a multiple layer including a plurality of insulating layers.

A gate spacer GS may be provided. A pair of gate spacers GS may be disposed on both sides of the gate electrode GE. The gate electrode GE and the gate insulating layer GI may be provided between the pair of gate spacers GS. The gate spacer GS may be provided on an uppermost semiconductor pattern SP. The gate spacer GS may include an insulating material. In some embodiments, the gate spacer GS may be a multiple layer including a plurality of insulating layers.

A gate capping pattern GP may be provided. The gate capping pattern GP may be provided on the gate electrode GE. The gate capping pattern GP may be provided between the pair of gate spacers GS. The gate capping pattern GP may include an insulating material. In some embodiments, the gate capping pattern GP may be a multiple layer including a plurality of insulating layers.

A first insulating layer 110 may be provided. The first insulating layer 110 may be provided on the source/drain pattern SD and the gate spacer GS. A second insulating layer 120 may be provided on the first insulating layer 110. The second insulating layer 120 may be provided on the gate spacer GS and the gate capping pattern GP. The first and second insulating layers 110 and 120 may include an insulating material. As an example, the first and second insulating layers 110 and 120 may include an oxide. In some embodiments, the first and second insulating layers 110 and 120 may be multiple layers including a plurality of insulating layers.

An active contact AC penetrating through the first and second insulating layers 110 and 120 in the third direction D3 may be provided. The active contact AC may be electrically connected to the source/drain pattern SD. The active contact AC may include a conductive material.

In some embodiments, a metal-silicide layer may be provided between the active contact AC and the source/drain pattern SD. In some embodiments, the active contact AC may include a barrier layer and a conductive layer on the barrier layer, and the barrier layer and the conductive layer may include different conductive materials.

Referring to FIG. 1D, the source/drain pattern SD may include an overlap portion OV, a first side portion S1, and a second side portion S2. The overlap portion OV may be a portion overlapping the fin pattern FP in the third direction D3. The first side portion S1 and the second side portion S2 may be spaced apart from each other in the second direction D2. The overlap portion OV may be disposed between the first side portion S1 and the second side portion S2. The overlap portion OV may connect the first side portion S1 and the second side portion S2.

A volume of the overlap portion OV may be greater than that of the first side portion S1 and that of the second side portion S2. In some embodiments, the volume of the overlap portion OV may be less than that of the first side portion S1. The volume of the first side portion S1 may be greater than that of the second side portion S2.

A maximum width of the overlap portion OV in the second direction D2 may be greater than that of the first side portion S1 in the second direction D2 and that of second side portion S2 in the second direction D2. In some embodiments, the maximum width of the overlap portion OV in the second direction D2 may be less than that of the first side portion S1 in the second direction D2. The maximum width of the first side portion S1 in the second direction D2 may be greater than that of the second side portion S2 in the second direction D2.

A maximum length of the overlap portion OV in the third direction D3 may be greater than that of the first side portion S1 in the third direction D3. In some embodiments, the maximum length of the overlap portion OV in the third direction D3 may be less than that of the first side portion S1 in the third direction D3. The maximum length of the first side portion S1 in the third direction D3 may be greater than that of the second side portion S2 in the third direction D3.

The source/drain pattern SD may include a first lower sidewall LS1, a second lower sidewall LS2, a first upper sidewall US1, a second upper sidewall US2, a lower surface SD_L, and an upper surface SD_U. The first lower sidewall LS1 and the second lower sidewall LS2 may be opposite to each other. The first upper sidewall US1 and the second upper sidewall US2 may be opposite to each other. Each of the first lower sidewall LS1, the second lower sidewall LS2, the first upper sidewall US1, and the second upper sidewall US2 may be flat.

The first lower sidewall LS1 and the second lower sidewall LS2 may be spaced apart from each other. The lower surface SD_L of the source/drain pattern SD may connect the first lower sidewall LS1 and the second lower sidewall LS2. The lower surface SD_L of the source/drain pattern SD may be disposed between the first lower sidewall LS1 and the second lower sidewall LS2.

The first upper sidewall US1 and the second upper sidewall US2 may be spaced apart from each other. The upper surface SD_U of the source/drain pattern SD may connect the first upper sidewall US1 and the second upper sidewall US2. The upper surface SD_U of the source/drain pattern SD may be disposed between the first upper sidewall US1 and the second upper sidewall US2.

The first lower sidewall LS1, the second lower sidewall LS2, the first upper sidewall US1, the second upper sidewall US2, and the upper surface SD_U of the source/drain pattern SD may be in contact with the first insulating layer 110. The lower surface SD_L of the source/drain pattern SD may be in contact with an upper surface FP_U of the fin pattern FP.

A length of the first lower sidewall LS1 may be less than that of the second lower sidewall LS2. For example, the length of the first lower sidewall LS1 in the cross-sectional view according to FIG. 1D may be less than that of the second lower sidewall LS2 in the cross-sectional view according to FIG. 1D.

In some embodiments, a length of the first upper sidewall US1 may be the same as that of the second upper sidewall US2. For example, the length of the first upper sidewall US1 in the cross-sectional view according to FIG. 1D may be the same as that of the second upper sidewall US2 in the cross-sectional view according to FIG. 1D.

The first lower sidewall LS1 may be a surface of the first side portion S1. The first upper sidewall US1 may be a surface of the first side portion S1. The second lower sidewall LS2 may be a surface of the second side portion S2. The second upper sidewall US2 may include a surface of the second side portion S2 and a surface of the overlap portion OV. The upper surface SD_U of the source/drain pattern SD may include a surface of the first side portion S1 and a surface of the overlap portion OV. The lower surface SD_L of the source/drain pattern SD may be a surface of the overlap portion OV.

In the cross-sectional view according to FIG. 1D, a point where the first lower sidewall LS1 and the first upper sidewall US1 are connected may be defined as a first point P1. A point where the second lower sidewall LS2 and the second upper sidewall US2 are connected may be defined as a second point P2. A point where the first upper sidewall US1 and the upper surface SD_U of the source/drain pattern SD are connected may be defined as a third point P3. A point where the second upper sidewall US2 and the upper surface SD_U of the source/drain pattern SD are connected may be defined as a fourth point P4. A point where the first lower sidewall LS1 and the lower surface SD_L of the source/drain pattern SD are connected may be defined as a fifth point P5. A point where the second lower sidewall LS2 and the lower surface SD_L of the source/drain pattern SD are connected may be defined as a sixth point P6.

In the cross-sectional view according to FIG. 1D, the first point P1 may be an uppermost portion of the first lower sidewall LS1 and a lowermost portion of the first upper sidewall US1. The second point P2 may be an uppermost portion of the second lower sidewall LS2 and a lowermost portion of the second upper sidewall US2. The third point P3 may be an uppermost portion of the first upper sidewall US1 and a lowermost portion of the upper surface SD_U of the source/drain pattern SD. The fourth point P4 may be an uppermost portion of the source/drain pattern SD. The fourth point P4 may be an uppermost portion of the second upper sidewall US2 and an uppermost portion of the upper surface SD_U of the source/drain pattern SD. The fifth point P5 may be a lowermost portion of the first lower sidewall LS1. The sixth point P6 may be a lowermost portion of the second lower sidewall LS2.

A level of the lowermost portion P5 of the first lower sidewall LS1 may be the same as that of the lowermost portion P6 of the second lower sidewall LS2. A level of the uppermost portion P1 of the first lower sidewall LS1 may be lower than that of the uppermost portion P2 of the second lower sidewall LS2. A level of the lowermost portion P1 of the first upper sidewall US1 may be lower than that of the lowermost portion P2 of the second upper sidewall US2. A level of the uppermost portion P3 of the first upper sidewall US1 may be lower than that of the uppermost portion P4 of the second upper sidewall US2.

A distance between the first point P1 and the overlap portion OV in the second direction D2 may be defined as a first distance L1. A distance between the second point P2 and the overlap portion OV in the second direction D2 may be defined as a second distance L2. The first distance L1 may be greater than the second distance L2.

The first distance L1 may be a maximum width of the first side portion S1 in the second direction D2. The second distance L2 may be a maximum width of the second side portion S2 in the second direction D2.

The fin pattern FP may include a first sidewall FP_S1 adjacent to the first lower sidewall LS1 and a second sidewall FP_S2 adjacent to the second lower sidewall LS2. The first sidewall FP_S1 and the second sidewall FP_S2 of the fin pattern FP may be opposite to each other. The first sidewall FP_S1 of the fin pattern FP and the first lower sidewall LS1 may be connected at the fifth point P5. The second sidewall FP_S2 of the fin pattern FP and the second lower sidewall LS2 may be connected at the sixth point P6.

An angle between the first sidewall FP_S1 of the fin pattern FP and the first lower sidewall LS1 may be defined as a first angle A1. An angle between the second sidewall FP_S2 of the fin pattern FP and the second lower sidewall LS2 may be defined as a second angle A2. The first angle A1 may be less than the second angle A2.

A first virtual line SL1 extending in a direction opposite to the second direction D2 from the fifth point P5 may be defined. A second virtual line SL2 extending in the second direction D2 from the sixth point P6 may be defined. A third virtual line SL3 extending in the direction opposite to the second direction D2 from the first point P1 may be defined. A fourth virtual line SL4 extending in the second direction D2 from the second point P2 may be defined.

The first to fourth virtual lines SL1, SL2, SL3, and SL4 may be parallel to the upper surface 100_U of the substrate 100. The first to fourth virtual lines SL1, SL2, SL3, and SL4 may be parallel to the second direction D2.

In the cross-sectional view according to FIG. 1D, an angle between the first virtual line SL1 and the first lower sidewall LS1 may be defined as a third angle A3. The first lower sidewall LS1 may be inclined at the third angle A3 with respect to the upper surface 100_U of the substrate 100.

In the cross-sectional view according to FIG. 1D, an angle between the second virtual line SL2 and the second lower sidewall LS2 may be defined as a fourth angle A4. The second lower sidewall LS2 may be inclined at the fourth angle A4 with respect to the upper surface 100_U of the substrate 100.

In the cross-sectional view according to FIG. 1D, an angle between the third virtual line SL3 and the first upper sidewall US1 may be defined as a fifth angle A5. The first upper sidewall US1 may be inclined at the fifth angle A5 with respect to the upper surface 100_U of the substrate 100.

In the cross-sectional view according to FIG. 1D, an angle between the fourth virtual line SL4 and the second upper sidewall US2 may be defined as a sixth angle A6. The second upper sidewall US2 may be inclined at the sixth angle A6 with respect to the upper surface 100_U of the substrate 100.

The third angle A3 may be less than the fourth angle A4. The fifth angle A5 may be less than the sixth angle A6. The third angle A3, at which the first lower sidewall LS1 is inclined with respect to the upper surface 100_U of the substrate 100, may be less than the fourth angle A4, at which the second lower sidewall LS2 is inclined with respect to the upper surface 100_U of the substrate 100. The fifth angle A5, at which the first upper sidewall US1 is inclined with respect to the upper surface 100_U of the substrate 100, may be less than the sixth angle A6, at which the second upper sidewall US2 is inclined with respect to the upper surface 100_U of the substrate 100.

The upper surface SD_U of the source/drain pattern SD may be inclined with respect to the upper surface 100_U of the substrate 100.

The first point P1 may be disposed in the first side portion S1. The second point P2 may be disposed in the second side portion S2. The third point P3 may be disposed in the first side portion S1. The fourth point P4 may be disposed in the overlap portion OV. The fifth point P5 may be a point where the first side portion S1 and the overlap portion OV are connected. The sixth point P6 may be a point where the second side portion S2 and the overlap portion OV are connected. The fourth point P4 may overlap the fin pattern FP in the third direction D3. The first, second, and third points P1, P2, and P3 may not overlap the fin pattern FP in the third direction D3.

The first and second lower sidewalls LS1 and LS2, and the first and second upper sidewalls US1 and US2 may be a {111} crystal plane of the source/drain pattern SD. The upper surface SD_U of the source/drain pattern SD may be a {100} crystal plane of the source/drain pattern SD. The {100} crystal plane of the source/drain pattern SD may be one of the (100), (010), (001), (−100), (0-10), or (00-1) crystal planes of the source/drain pattern SD. The {111} crystal plane of the source/drain pattern SD may be one of the (111), (11-1), (1-11), (1-1-1), (−111), (−11-1), (−1-11), or (−1-1-1) crystal planes of the source/drain pattern SD.

The upper surface 100_U of the substrate 100 may be inclined at a seventh angle A7 with respect to a {100} crystal plane 101 of the substrate 100. The seventh angle A7 may be, for example, 4 degrees to 10 degrees. However, the seventh angle A7 may not be limited thereto. The crystal plane 101 of the substrate 100 may be one of the (100), (010), (001), (−100), (0-10), or (00-1) crystal planes of the substrate 100.

In some embodiments, the first sidewall FP_S1 and the second sidewall FP_S2 of the fin pattern FP may be inclined at the seventh angle A7 with respect to a {111} crystal plane of the substrate 100. The {111} crystal plane of the substrate 100 may be one of the (111), (11-1), (1-11), (1-1-1), (−111), (−11-1), (−1-11), or (−1-1-1) crystal planes of the substrate 100.

Referring to FIGS. 1A to 1D, the first direction D1 may be parallel to a <110> direction of the substrate 100. The second direction D2 may be inclined at the seventh angle A7 in the <110> direction of the substrate 100. The third direction D3 may be inclined at the seventh angle A7 in a <100> direction of the substrate 100. The first direction D1 may be parallel to a <110> direction of the semiconductor pattern SP. The <110> direction of the substrate 100 may be one of the [110], [1-10], [−1-10], [101], [−101], [10-1], [−10-1], [011], [0-11], [01-1], or [0-1-1] directions of the substrate 100. The <100> direction of the substrate 100 may be one of the [100], [−100], [010], [001], or [00-1] directions of the substrate 100. The <110> direction of the semiconductor pattern SP may be one of the [110], [−110], [1-10], [−1-10], [101], [−101], [10-1], [−10-1], [011], [0-11], [01-1], or [0-1-1] directions of the semiconductor pattern SP.

In the semiconductor device according to some embodiments, as the upper surface 100_U of the substrate 100 is inclined with respect to the {100} crystal plane of the substrate 100, the source/drain pattern SD may have a shape inclined with respect to the upper surface 100_ U of the substrate 100. Accordingly, a distance between source/drain patterns SD adjacent to each other may be relatively large, and a bridging between the source/drain patterns SD may be prevented.

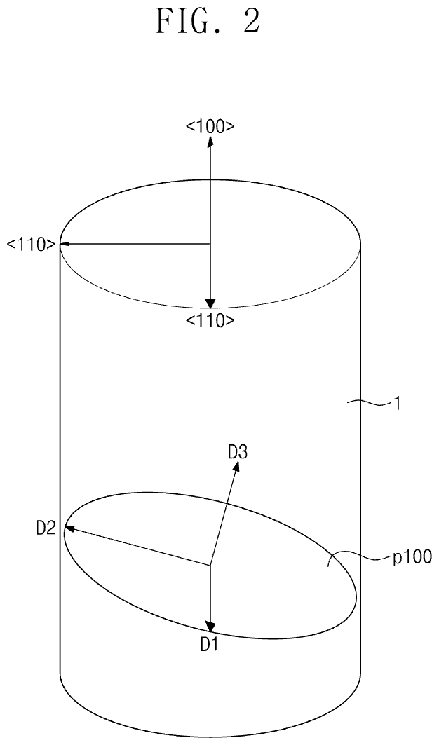

FIGS. 2, 3, 4, 5A, and 5B are diagrams for describing a method of manufacturing a semiconductor device according to some embodiments.

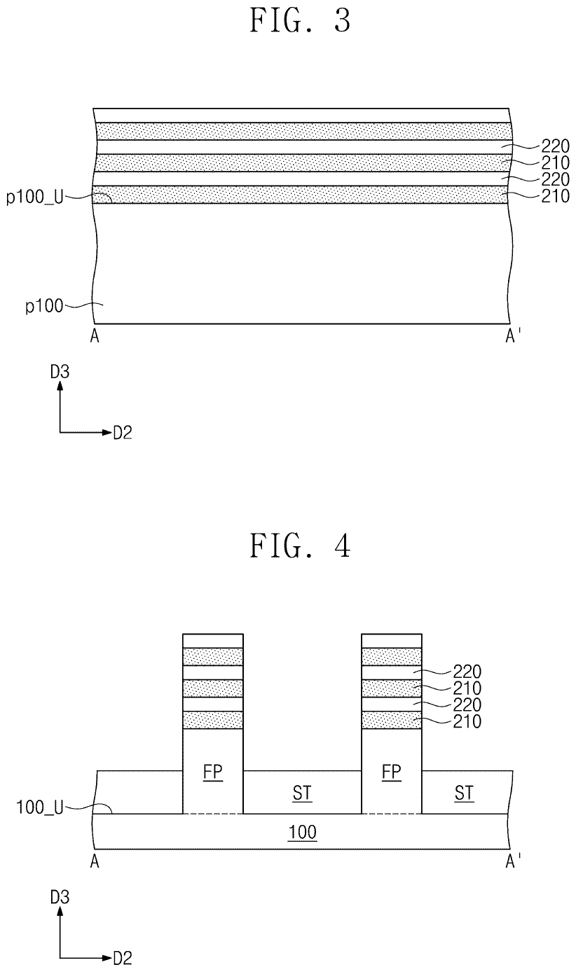

Referring to FIGS. 2 and 3, a preliminary substrate p100 may be formed. Forming the preliminary substrate p100 may include cutting an ingot 1 to form the preliminary substrate p100. The preliminary substrate p100 may be formed such that an upper surface p100_U of the preliminary substrate p100 is inclined with respect to a {100} crystal plane of the ingot 1. The ingot 1 may comprise a semiconductor material. For example, the ingot 1 may comprise silicon.

The upper surface p100_U of the preliminary substrate p100 may be parallel to a plane defined by the first direction D1 and the second direction D2. The upper surface p100_U of the preliminary substrate p100 may be orthogonal to the third direction D3. The first direction D1 may be parallel to a <110> direction of the ingot 1. The second direction D2 may be inclined with respect to the <110> direction of the ingot 1. The third direction D3 may be inclined with respect to a <100> direction of the ingot 1.

A sacrificial layer 210 and a semiconductor layer 220 may be formed on the preliminary substrate p100. The sacrificial layer 210 and the semiconductor layer 220 may be alternately stacked on each other along the third direction D3. The sacrificial layer 210 and the semiconductor layer 220 may include different materials. A material included in the sacrificial layer 210 may have an etch selectivity with respect to a material included in the semiconductor layer 220. In an example, the sacrificial layer 210 may include silicon-germanium, and the semiconductor layer 220 may include silicon.

Referring to FIG. 4, the sacrificial layer 210, the semiconductor layer 220, and the preliminary substrate p100 may be etched. The sacrificial layer 210 may be etched and separated into a plurality of the sacrificial layers 210. The semiconductor layer 220 may be etched and separated into a plurality of the semiconductor layers 220.

The preliminary substrate p100 may be etched to form the fin pattern FP and the substrate 100. The preliminary substrate p100 may be etched to define the upper surface 100_U of the substrate 100. The preliminary substrate p100 may be etched so that the upper surface 100_U of the substrate 100 is inclined with respect to the {100} crystal plane of the substrate 100. The device isolation layer ST may be formed.

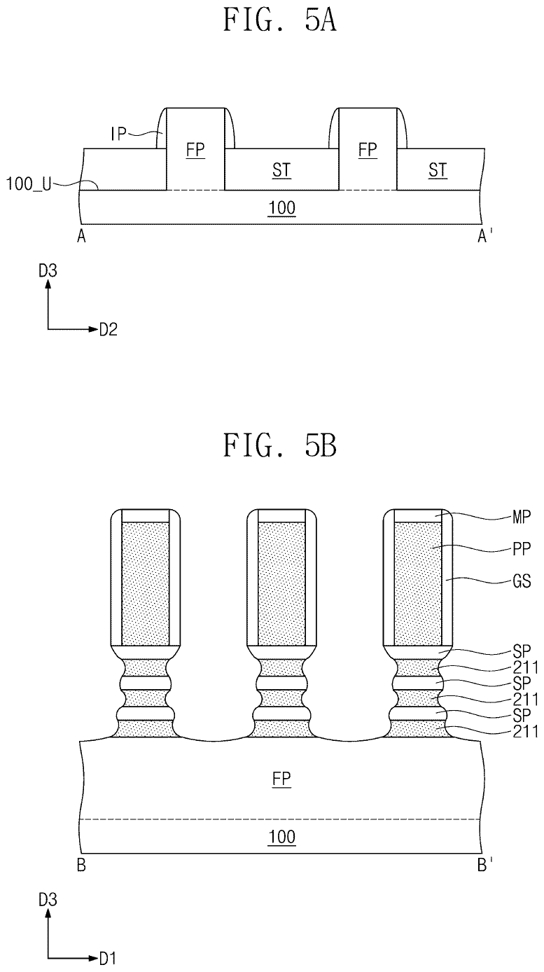

Referring to FIGS. 5A and 5B, a gate sacrificial pattern PP and a mask pattern MP may be formed. Forming the gate sacrificial pattern PP and the mask pattern MP may include forming a preliminary pattern layer, forming the mask pattern MP on the preliminary pattern layer, and patterning the preliminary pattern layer using the mask pattern MP as an etching mask. The preliminary pattern layer may be patterned to form the gate sacrificial pattern PP.

The gate sacrificial pattern PP may include, for example, polysilicon. The mask pattern MP may include, for example, an insulating material. The gate sacrificial pattern PP may extend in the second direction D2. The gate sacrificial pattern PP may overlap the fin pattern FP in the third direction D3.

The mask pattern MP may be provided on the gate sacrificial pattern PP. The mask pattern MP may extend in the second direction D2.

The gate spacer GS may be formed on sidewalls of the gate sacrificial pattern PP and the mask pattern MP.

The sacrificial layer 210 and the semiconductor layer 220 may be etched using the mask pattern MP and the gate spacer GS as an etching mask. The semiconductor layer 220 may be etched to form a plurality of the semiconductor patterns SP. The semiconductor layer 220 may be separated into a plurality of the semiconductor patterns SP. The sacrificial layer 210 may be etched to form a plurality of sacrificial patterns 211. The sacrificial layer 210 may be separated into a plurality of the sacrificial patterns 211.

In the process of etching the sacrificial layer 210 and the semiconductor layer 220, the fin pattern FP may be etched together with the sacrificial layer 210 and the semiconductive layer 220.

The insulation pattern IP may be formed. Forming the insulating pattern IP may include forming a preliminary insulating layer, and etching the preliminary insulating layer to form the insulating pattern IP. The preliminary insulating layer may include an insulating material.

The preliminary insulating layer may be formed before etching the sacrificial layer 210 and the semiconductor layer 220. The preliminary insulating layer may cover the sacrificial layer 210 and the semiconductor layer 220. In the process of etching the sacrificial layer 210 and the semiconductor layer 220, the preliminary insulating layer may be etched together with the sacrificial layer 210 and the semiconductive layer 220, and the insulating pattern IP may be formed.

Referring to FIGS. 1A to 1C, the source/drain pattern SD may be formed. The source/drain pattern SD may be formed through an epitaxial growth process that seeds the semiconductor pattern SP and the sacrificial pattern 211. The first insulating layer 110 may be formed.

The sacrificial pattern 211, the mask pattern MP, and the gate sacrificial pattern PP may be removed. The sacrificial pattern 211, the mask pattern MP, and the gate sacrificial pattern PP may be removed to form the gate insulating layer GI, the gate electrodes GE, and the gate capping pattern GP in the formed empty space.

The second insulating layer 120 may be formed. The active contact AC may be formed.

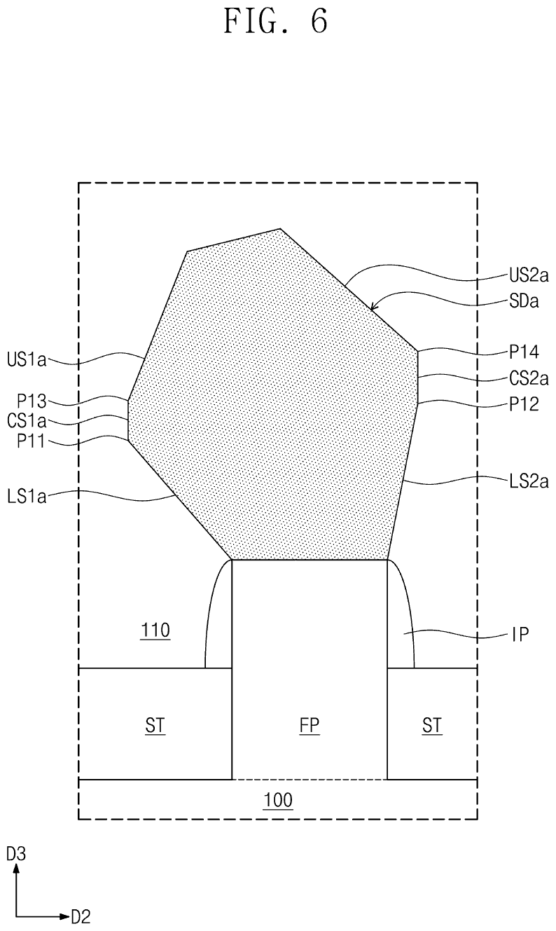

FIG. 6 is an enlarged cross-sectional view of a semiconductor device according to some embodiments. The semiconductor device according to FIG. 6 may be similar to the semiconductor device according to FIGS. 1A to 1D, except as described below.

Referring to FIG. 6, a source/drain pattern SDa may include a first connecting sidewall CS1a connecting a first lower sidewall LS1a and a first upper sidewall US1a. The source/drain pattern SDa may include a second connecting sidewall CS2a connecting a second lower sidewall LS2a and a second upper sidewall US2a.

The first connecting sidewall CS1a may be disposed between the first lower sidewall LS1a and the first upper sidewall US1a. The second connecting sidewall CS2a may be disposed between the second lower sidewall LS2a and the second upper sidewall US2a.

A level of a lowermost portion P11 of the first connection sidewall CS1a may be lower than that of a lowermost portion P12 of the second connection sidewall CS2a. A level of an uppermost portion P13 of the first connection sidewall CS1a may be lower than that of an uppermost portion P14 of the second connection sidewall CS2a.

The level of the uppermost portion P13 of the first connection sidewall CS1a may be higher than that of the lowermost portion P12 of the second connection sidewall CS2a.

A level of a lowermost portion P13 of the first upper sidewall US1a may be higher than that of an uppermost portion P12 of the second lower sidewall LS2a.

The first and second lower sidewalls LS1a and LS2a, and the first and second upper sidewalls US1a and US2a may be a {111} crystal plane of the source/drain pattern SDa. The first connection sidewall CS1a and the second connection sidewall CS2a may be inclined with respect to the {111} crystal plane of the source/drain pattern SDa.

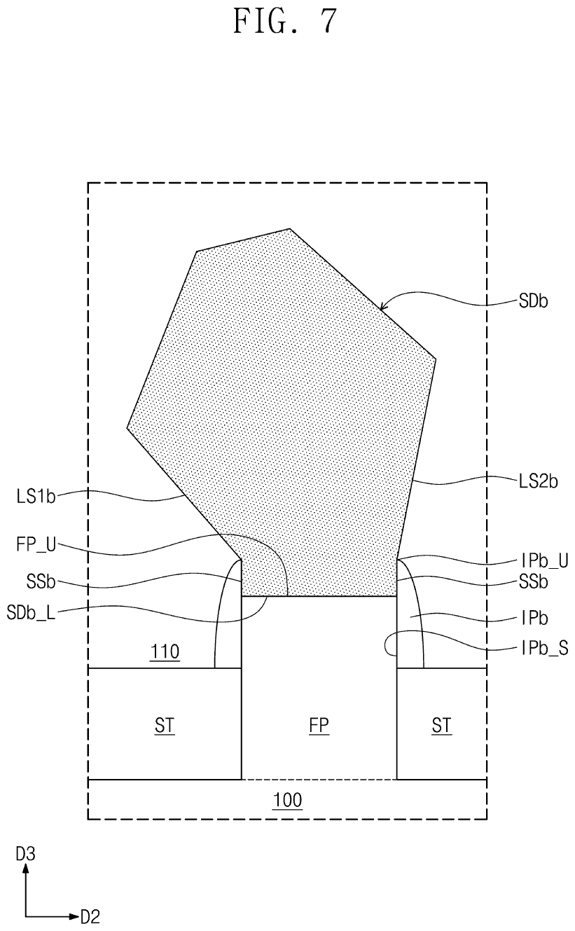

FIG. 7 is an enlarged cross-sectional view of a semiconductor device according to some embodiments. The semiconductor device according to FIG. 7 may be similar to the semiconductor device according to FIGS. 1A to 1D, except as described below.

Referring to FIG. 7, a source/drain pattern SDb may include a surface SSb that is in contact with a sidewall IPb_S of an insulating pattern IPb. The surface SSb of the source/drain pattern SDb may be connected to a lower surface SDb_L of the source/drain pattern SDb. The surface SSb of the source/drain pattern SDb may be connected to a first lower sidewall LS1b or a second lower sidewall LS2b of the source/drain pattern SDb.

The surface SSb of the source/drain pattern SDb may be disposed between the lower surface SDb_L of the source/drain pattern SDb and the first lower sidewall LS1b, or between the lower surface SDb_L of the source/drain pattern SDb and the second lower sidewall LS2b. The surface SSb of the source/drain pattern SDb may be a surface of a portion of the source/drain pattern SDb disposed between the insulating patterns IPb.

The surface SSb of the source/drain pattern SDb may be disposed at a lower level than the first lower sidewall LS1b and the second lower sidewall LS2b of the source/drain pattern SDb.

The first and second lower sidewalls LS1b, LS2b of the source/drain pattern SDb may be crystal plane of the source/drain pattern SDb. The surface SSb of the source/drain pattern SDb may be inclined with respect to the {111} crystal plane of the source/drain pattern SDb.

A level of the lower surface SDb_L of the source/drain pattern SDb may be lower than that of an uppermost portion IPb_U of the insulating pattern IPb. A level of the upper surface FP_U of the fin pattern FP may be lower than that of the uppermost portion IPb_U of the insulating pattern IPb.

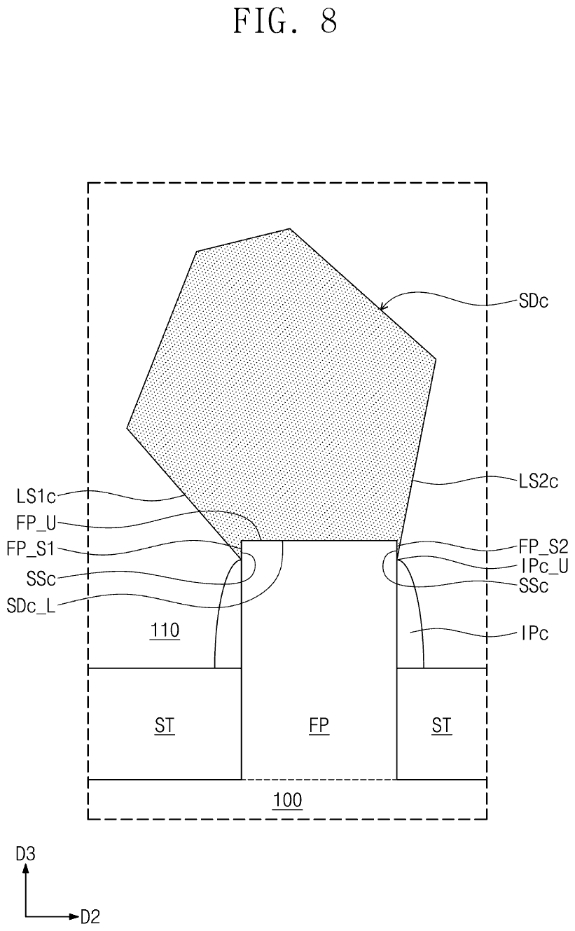

FIG. 8 is an enlarged cross-sectional view of a semiconductor device according to some embodiments. The semiconductor device according to FIG. 8 may be similar to the semiconductor device according to FIGS. 1A to 1D, except as described below.

Referring to FIG. 8, a source/drain pattern SDc may include a surface SSc that in in contact with the first sidewall FP_S1 or the second sidewall FP_S2 of the fin pattern FP. The surface SSc of the source/drain pattern SDc may be connected to a lower surface SDc_L of the source/drain pattern SDc. The surface SSc of the source/drain pattern SDc may be connected to a first lower sidewall LS1c or a second lower sidewall LS2c of the source or drain pattern SDc.

The surface SSc of the source/drain pattern SDc may be disposed between the lower surface SDc_L of the source/drain pattern SDc and the first lower sidewall LS1c, or between the lower surface SDc_L of the source/drain pattern SDc and the second lower sidewall LS2c. The surface SSc of the source/drain pattern SDc may be disposed between the first sidewall FP_S1 of the fin pattern FP and the first lower sidewall LS1c of the source/drain pattern SDc, or between the second sidewall FP_S2 of the fin pattern FP and the second lower sidewall LS2c of the source/drain pattern SDc.

The surface SSc of the source/drain pattern SDc may be disposed at a higher level than a lowermost portion of the first lower sidewall LS1c and a lowermost portion of the second lower sidewall LS2c in the source/drain pattern SDc.

The first and second lower sidewalls LS1c and LS2c of the source/drain pattern SDc may be a {111} crystal plane of the source/drain pattern SDc. The surface SSc of the source/drain pattern SDc may be inclined with respect to the {111} crystal plane of the source/drain pattern SDc.

A level of the lower surface SDc_L of the source/drain pattern SDc may be higher than that of an uppermost portion IPc_U of an insulating pattern IPc. A level of the upper surface FP_U of the fin pattern FP may be higher than that of the uppermost portion IPc_U of the insulating pattern IPc.

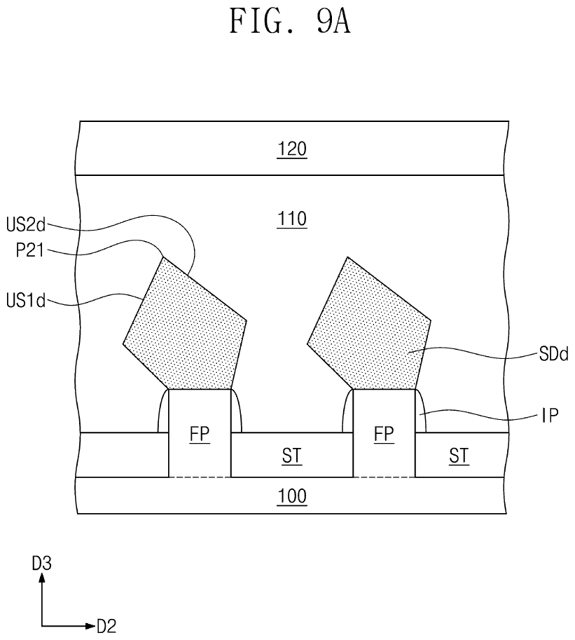

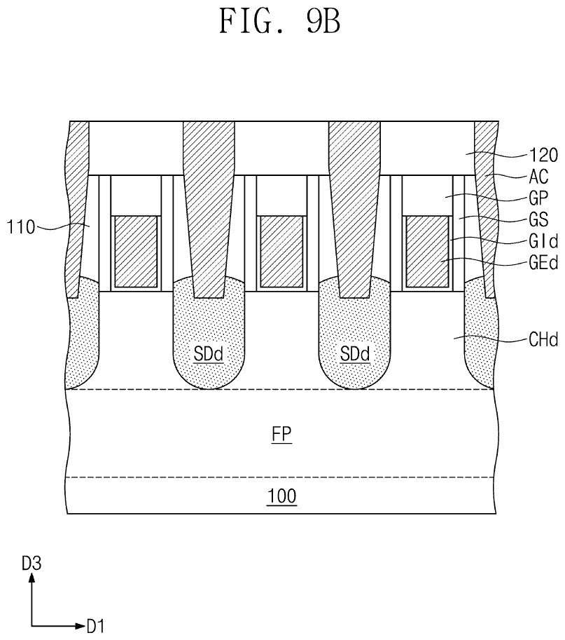

FIGS. 9A and 9B are cross-sectional views of a semiconductor device according to some embodiments. The semiconductor device according to FIGS. 9A and 9B may be similar to the semiconductor device according to FIGS. 1A to 1D, except as described below.

Referring to FIGS. 9A and 9B, a channel structure CHd, the fin pattern FP, and the substrate 100 may include the same material as each other. The channel structure CHd, the fin pattern FP and the substrate 100 may be connected to each other and have an integral structure without boundaries.

In some embodiments, the substrate 100 may be omitted, and the fin pattern FP may be provided on a lower insulating layer. In this case, the fin pattern FP and the channel structure CHd may be integrally connected to each other without boundaries, including a semiconductor material. Alternatively, the fin pattern FP may include an insulating material, and the channel structure CHd may include a semiconductor material.

A gate electrode GEd may overlap the channel structure CHd in the third direction D3. A portion of the gate electrode GEd overlap the channel structure CHd in the third direction D3 may be disposed at a higher level than the channel structure CHd. The gate electrode GEd and the channel structure CHd may constitute, for example, a FinFET. The gate electrode GEd may include a conductive material.

A gate insulating layer GId may be provided. The gate insulating layer GId may be in contact with the gate electrode GEd and the channel structure CHd. The gate insulating layer GId may be spaced apart from a source/drain pattern SDd. The gate spacer GS may be provided between the gate insulating layer GId and the source/drain pattern SDd. The gate insulating layer GId may include an insulating material. For example, the gate insulating layer GId may include an oxide. In some embodiments, the gate insulating layer GId may be a multiple layer including a plurality of insulating layers.

In the cross-sectional view according to FIG. 9A, a point where a first upper sidewall US1d and a second upper sidewall US2d of the source/drain pattern SDd are connected may be defined as a first point P21. The first point P21 may be an uppermost portion of the source/drain pattern SDd. The first point P21 may be an uppermost portion of the first upper sidewall US1d and an uppermost portion of the second upper sidewall US2d.

The source/drain pattern SDd may include an overlap portion, a first side portion, and a second side portion. The first point P21 may be disposed in the first side portion.

A semiconductor device according to embodiments of the present inventive concept may have a shape in which a source/drain pattern is inclined with respect to an upper surface of a substrate. Accordingly, a distance between source/drain patterns adjacent to each other may be relatively large, and a bridging between the source/drain patterns may be prevented.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device comprising:
a fin pattern;
a source/drain pattern disposed on the fin pattern;
a channel structure connected to the source/drain pattern; and
a gate electrode overlapping the channel structure,
wherein the source/drain pattern comprises:
an overlap portion overlapping with the fin pattern; and
a first side portion and a second side portion spaced apart from each other with the overlap portion interposed therebetween,
wherein the first side portion comprises a first lower sidewall,
wherein the second side portion comprises a second lower sidewall opposite to the first lower sidewall,
wherein a level of an uppermost portion of the first lower sidewall is lower than that of a lowermost portion of the second lower sidewall, and
wherein a volume of the first side portion is larger than that of the second side portion.

2. The semiconductor device of claim 1, wherein the fin pattern comprises a first sidewall adjacent to the first lower sidewall and a second sidewall adjacent to the second lower sidewall, and
wherein an angle between the first lower sidewall and the first sidewall of the fin pattern is less than that between the second lower sidewall and the second sidewall of the fin pattern.

3. The semiconductor device of claim 1, further comprising a substrate connected to the fin pattern,
wherein the first side portion comprises a first upper sidewall,
wherein the second side portion comprises a second upper sidewall opposite to the first upper sidewall,
wherein the first upper sidewall is inclined at a first angle with respect to an upper surface of the substrate,
wherein the second upper sidewall is inclined at a second angle with respect to the upper surface of the substrate, and
wherein the first angle is less than the second angle.

4. The semiconductor device of claim 3, wherein the upper surface of the substrate is inclined with respect to a {100} crystal plane of the substrate.

5. The semiconductor device of claim 3, wherein a level of an uppermost portion of the first upper sidewall is lower than that of an uppermost portion of the second upper sidewall.

6. The semiconductor device of claim 3, wherein the first side portion comprises a first connecting sidewall connecting the first lower sidewall and the first upper sidewall, and
wherein the second side portion comprises a second connecting sidewall connecting the second lower sidewall and the second upper sidewall,
wherein a level of a lowermost portion of the first connecting sidewall is lower than that of a lowermost portion of the second connecting sidewall, and
wherein a level of an uppermost portion of the first connection sidewall is lower than that of an uppermost portion of the second connection sidewall.

7. The semiconductor device of claim 6, wherein the level of the uppermost portion of the first connection sidewall is higher than that of the lowermost portion of the second connection sidewall.

8. A semiconductor device comprising:
a substrate;
a fin pattern disposed on the substrate;
a source/drain pattern disposed on the fin pattern;
a channel structure connected to the source/drain pattern; and
a gate electrode overlapping the channel structure,
wherein an upper surface of the substrate is inclined at a first angle with respect to a {100} crystal plane of the substrate.

9. The semiconductor device of claim 8, wherein the source/drain pattern comprises:
a first lower sidewall; and
a second lower sidewall opposite the first lower sidewall,
wherein a length of the second lower sidewall is greater than that of the first lower sidewall.

10. The semiconductor device of claim 9, wherein the first lower sidewall is inclined at a second angle with respect to the upper surface of the substrate,
wherein the second lower sidewall is inclined at a third angle with respect to the upper surface of the substrate, and
wherein the second angle is less than the third angle.

11. The semiconductor device of claim 9, wherein a level of a lowermost portion of the first lower sidewall and a level of a lowermost portion of the second lower sidewall are the same.

12. The semiconductor device of claim 9, wherein the first lower sidewall and the second lower sidewall are {111} crystal planes of the source/drain pattern.

13. The semiconductor device of claim 8, wherein the source/drain pattern comprises:
a first upper sidewall;
a second upper sidewall opposite the first upper sidewall; and
an upper surface connecting the first upper sidewall and the second upper sidewall,
wherein the upper surface of the source/drain pattern is inclined with respect to the upper surface of the substrate.

14. The semiconductor device of claim 13, wherein the source/drain pattern comprises:
a first lower sidewall;
a second lower sidewall opposite the first lower sidewall;
a first connecting sidewall connecting the first lower sidewall and the first upper sidewall; and
a second connecting sidewall connecting the second lower sidewall and the second upper sidewall,
wherein the first and second upper sidewalls, and the first and second lower sidewalls are {111} crystal planes of the source/drain pattern, and
wherein the first and second connection sidewalls are inclined with respect to the {111} crystal planes of the source/drain pattern.

15. The semiconductor device of claim 8, wherein a sidewall of the fin pattern is inclined with respect to a {111} crystal plane of the substrate.

16. A semiconductor device comprising:
a fin pattern;
a source/drain pattern disposed on the fin pattern;
a channel structure connected to the source/drain pattern;
a gate insulating layer disposed on the channel structure;
a gate electrode disposed on the gate insulating layer; and
an active contact disposed on the source/drain pattern,
wherein the source/drain pattern comprises:
an overlap portion overlapping with the fin pattern; and
a first side portion and a second side portion spaced apart from each other with the overlap portion interposed therebetween,
wherein the first side portion comprises a first lower sidewall,
wherein the second side portion comprises a second lower sidewall opposite to the first lower sidewall,
wherein the fin pattern comprises a first sidewall adjacent the first lower sidewall and a second sidewall adjacent the second lower sidewall,
wherein an angle between the first lower sidewall and the first sidewall of the fin pattern is less than that between the second lower sidewall and the second sidewall of the fin pattern, and
wherein a volume of the first side portion is larger than that of the second side portion.

17. The semiconductor device of claim 16, wherein a distance between an uppermost portion of the first lower sidewall and the overlap portion is greater than that between an uppermost portion of the second lower sidewall and the overlap portion.

18. The semiconductor device of claim 16, wherein a volume of the overlap portion is larger than that of the second side portion.

19. The semiconductor device of claim 16, wherein an uppermost portion of the source/drain pattern is disposed in the first side portion.

20. The semiconductor device of claim 16, wherein an uppermost portion of the source/drain pattern overlaps with the fin pattern.
